(19) United States
(12) Patent Application Publication
(10) Pub. No.: US 2026/0066616 A1
(43) Pub. Date: Mar. 5, 2026

(54) SPIN INJECTOR LIGHT EMISSION SYSTEM

(71) Applicants: THALES, MEUDON (FR); CENTRE NATIONAL DE LA RECHERCHE SCIENTIFIQUE, PARIS (FR); UNIVERSITE DE LORRAINE, NANCY CEDEX (FR)

(72) Inventors: Yuan LU, NANCY (FR); Jean-Marie GEORGE, PALAISEAU (FR); Henri JAFFRES, PALAISEAU (FR); Denis CRETE, PALAISEAU (FR)

(21) Appl. No.: 19/100,906

(22) PCT Filed: Jul. 28, 2023
(86) PCT No.: PCT/EP2023/071083

§ 371 Date: Feb. 3, 2025

(30) Foreign Application Priority Data
Aug. 4, 2022 (FR) FR2208077

(51) Int. Cl. H01S 5/042; H01S 5/183; H10H 20/831

(52) U.S. Cl. CPC H01S 5/04256; H01S 5/183; H10H 20/831

(57) ABSTRACT

A spin-LED or spin-laser light emission system includes a stack including an active layer and transport layers, an electrode as anode and an electrode as cathode, a spin injector, deposited on the stack and including an assembly of at least one first layer made of ferromagnetic material and at least one second layer made of metal material, the assembly having a bar structure being a Hall bar, a first electrode and a second electrode, being spin electrodes, configured to generate, in the Hall bar, a pulsed current along the axis X in a first direction or a second direction opposite the first direction, the spin injector having a magnetization along Z and such that reversal of the direction of the current reverses the direction of the magnetization, switching of the magnetization of the spin injector inducing a change in the circular polarization state of light emitted by the emission system.

### CROSS-REFERENCE TO RELATED APPLICATIONS

This application is a National Stage of International patent application PCT/EP2023/071083, filed on Jul. 28, 2023, which claims priority to foreign French patent application No. FR 2208077, filed on Aug. 4, 2022, the disclosures of which are incorporated by reference in their entireties.

### FIELD OF THE INVENTION

The present invention relates to a spin-LED or spin-laser light emission system, and more particularly to a light emission system that makes it possible to modulate the polarization of light emitted by the system.

### BACKGROUND

In recent years, due to the rise of new applications involving artificial intelligence, Big Data, the IoT and 5G, optical communication and optical interconnection technologies are being used increasingly in a variety of applications ranging from Internet data streams and supercomputers to large-scale data centers. These optical technologies make it possible to meet needs in terms of increasing communication capacity and speed and reducing energy consumption.

In current optical communication systems, signal transmission uses frequency or wavelength (dense wavelength division multiplexing or DWDM), phase (QPSK modulation or quadrature phase shift keying modulation) or amplitude (PAM4 modulation or pulse amplitude modulation 4-level) to carry out coding. It becomes very difficult to further increase transmission rate, capacity and bandwidth.

Polarization is the final adjustable physical parameter of light that is able to be influenced. At present, only linear polarization is used as a static parameter to improve parallel communication systems (DP-QPSK, DP-QAM, DP for dual polarization). High-speed direct modulation of light polarization and the additional use of the degree of freedom of circular polarization may serve as a basis for a new communication technology that makes it possible to overcome the rate limitations that are at present the main bottleneck in optical telecommunications.

Spintronic technology makes it possible to modulate the emitted circular polarization. Spin polarization of an electron is the term used to denote the spin state (up or down) of the electron. A spin-polarized electron is an electron having a controlled and known spin state (up or down). This electron will be called a “spin electron” hereinafter.

It has been demonstrated that the injection of spin electrons into an (LED or laser) emission device (referred to as spin injection) was able to generate a preferential polarization of light emitted in one of the two left-hand circular polarization (LHCP) or right-hand circular polarization (RHCP) states (see for example the publication “Injection and detection of a spin-polarized current in a light-emitting diode”, Nature, vol. 402 1999). The circular polarization rate (or polarization contrast) Pc of light is defined according to:

$$Pc = ( {σ}^{+} - {σ}^{-} ) / ( {σ}^{+} + {σ}^{-} )$$

with σ⁺, σ⁻ the light intensity (photon density) in the RHCP and LHCP polarization state, respectively.

Spin injection consists in injecting, from a ferromagnetic layer, which is generally made of metal, spin electrons (that is to say electrons having a spin polarization, that is to say a predominantly up or down spin state) into a conductive layer, the spin polarization of these injected electrons being at least partially transmitted to electrons carrying out electrical transportation (charge transportation) in the LED and/or the laser, which are then called a spin LED or spin laser.

In practice, a ferromagnetic layer is deposited as spin injector on the upper part of a vertical light-emitting diode or laser. One example, described in the journal publication “Spin Controlled Vertical Cavity Surface Emitting Lasers” by Nils C. Gerhardt et al (Advances in Optical technology, vol. 2012, Article ID268949), is illustrated in FIG. 1. a) schematically shows the stack of the spin LED and b) schematically shows the associated band diagram (the axis perpendicular to z corresponds to an energy axis). The LED is of conventional GaAs (or AlGaAs) p-i-n technology and has an active layer QD0 consisting of quantum dots (QD) based on InAs or InGaAs and n-GaAs, i-GaAs and p-GaAs transport layers deposited on a semiconductor substrate Sub0. The spin injector Slnj0 deposited on the n-GaAs layer comprises a ferromagnetic layer FML0 consisting of a ferromagnetic bilayer or multilayer, for example consisting of Fe/Tb, Co/Pt, Fe/Pt/Co/Ni, MnGa having a magnetization along z perpendicular to the plane of the layers. It is also preferable to use an additional insulating layer TLO, for example made of MgO (magnesium oxide), AlOx (alumina) or a Schottky barrier (thin enough to transmit electrons through the principle of the tunnel effect), making it possible to adapt the resistivity between the injector and the upper layer of the n-GaAs LED stack so as to obtain better spin injection efficiency. Two electrodes, a cathode C0 (n-contact, typically made of gold) and an anode A0 (p-contact, typically made of gold) make it possible to inject charge carriers (imposed by a current source CS0). The cathode C0 is deposited on the injector and the anode is in contact with the p-GaAs layer. Spin electrons are injected from the ferromagnetic layer, for example the bottom Fe layer of the Fe/Tb multilayer, or the like as described above, into the n-GaAs layer via the MgO layer (also referred to as tunnel barrier), and recombine with the non-polarized holes in the active layer QD0.

The injection of spin-polarized electrons into the LED/laser leads to the emission of circularly polarized light via optical selection rules describing the conservation of angular momentum during recombinations (quantum transitions) of electrons that change band. According to these optical selection rules, the circular polarization of emitted light is proportional to the electrically injected spin polarization. It is then possible to switch between the two LHCP and RHCP polarization states of light by reversing the direction of the magnetization of the ferromagnetic layer. On this basis, provided that the population reversal condition is met, the operation of the spin laser is achieved by adding an optical cavity to the semiconductor gain medium of the spin LED. The spin laser is generally an (external) vertical cavity surface-emitting laser or VCSEL.

Spin lasers have two inherent advantages. First of all, even with a small injection of spin-polarized electrons (2-3%), the spin laser is able to emit light with a circular polarization approaching 100%, thus acting as a spin amplifier. This is because the circular gain anisotropy induced by spin injection leads to a significant intensity imbalance between the two circular eigenmodes, due to the strong competition between modes in the active medium. This imbalance may generate complete switching between the two eigenmodes if the mode competition is high enough. The second advantage is that of reducing the threshold current by almost half compared to a “conventional” laser.

Recently, the publication “Electrical Initialization of Electron and Nuclear Spins in a Single Quantum dot at zero magneticfield” (Cadiz et al, Nano Letters, 18, 2381-2386, 2018) described a spin injector SinjO based on thin CoFeB ferromagnetic layers (with an electrode C0 made of tantalum Ta) deposited on an LED, the LED having a stack ST0 comprising an active layer AL0 comprising InGaAs/GaAs quantum dots (QD) and transport layers, as illustrated in FIG. 2. A current I0 applied to the device enables a light emission EL0. The polarization current of the device (for electroluminescence) and the spin electron current match. A polarization rate Pc of up to 35% was obtained with zero applied magnetic field, from a single QD. FIG. 2 illustrates the LED/spin injector stack and FIG. 3 illustrates the switch from one circular polarization to the other of the light emitted by the device of FIG. 2 as a function of an applied field Bₑₓₜ (at a temperature T=9 K and a current I0=490 μA). Applying the external field Bₑₓₜ makes it possible to change the direction of magnetization of the ferromagnetic layer of the injector (change its direction). Once the magnetization of the ferromagnetic layer has been switched, it is possible to abstain from applying the external field, which is used only for switching. The curve 30 illustrates the polarization switching with a change of Pc from −20% to +20% as a function of the value and orientation of the field Bₑₓₜ. The curve 31 illustrates the hysteresis loop of the magnetization (normalized to saturation magnetization) of the CoFeB ferromagnetic layer. The behavior of the polarization rate Pc as a function of the sign of the field Bₑₓₜ is in accordance with the hysteresis loop of the normalized magnetization of the CoFeB layer. The polarization of the emitted light is indeed characteristic of the polarization of the spin electrons, which are polarized by the magnetization of the ferromagnetic layer. From a fundamental point of view, this study shows a signature of the dynamic polarization of nuclear spins in the QD, induced by hyperfine interaction with the electrically injected electron spin.

The publication Liang et al (Physical Review B, 90, 085310, 2014) describes a spin injector magnetized perpendicularly to the plane of the layers formed by a stack of ultra-thin layers of MgO (2.5 nm)/CoFeB (1.2 nm)/Ta deposited on a QW GaAs LED (QW standing for quantum well). The value of Pc that was measured was 13% at 25 K and 8% at 300 K with zero magnetic field.

The application of strong magnetic fields using a conventional coil/electromagnet is not suitable for practical applications. With regard to criteria of speed and selective addressing of a particular element (of micrometric size) in an assembly arranged in an array or in a matrix, the challenge is to electrically switch or modulate the magnetization of the spin injector in order to control the output circular polarization, while avoiding any switching by way of an external magnetic field.

One electrical spin switching solution is based on fabricating, on the upper part of the spin VCSEL, a pair of spin injection electrodes Slnj1 and Slnj2 whose magnetization is anti-parallel (up spin and down spin), as illustrated in FIG. 4, taken from the publication “Spin polarization modulation for high-speed vertical-cavity surface-emitting lasers”, Yokota et al (Applied Physics Letters 113, 171102, 2018). Modulating and controlling the contribution of the current injected from each injector, via a modulation signal MSO, brings about the desired switching of helicity, that is to say the direction of the circular polarization (left-hand σ⁻ or right-hand σ⁺) of the emitted light EL0. The spin VCSEL of FIG. 4 comprises a transport layer TRAL, an active layer AL0, an oxide layer OxL0 delimiting the flow of electrons, two Bragg mirrors n-DBR0 and p-DBR0 forming the laser cavity and a hole injection electrode HIL. Two spin injectors having opposing magnetization are positioned on the transport layer TRAL. Each spin injector comprises a ferromagnetic/metal bilayer of Fe/Pt type or the like as mentioned above, so as ultimately to give a semiconductor/MgO/Fe/Pt structure.

Although this method is simple and practical, each polarization change requires a new step of injecting current into each spin electrode. Operation in continuous emission mode is therefore problematic. Compared to conventional light intensity modulation for telecommunications, this method is not competitive. Indeed, for a very high data rate or a very long-distance transmission, a laser source has to operate in continuous mode. This avoids the laser “chirp” effect, which widens the linewidth of directly modulated lasers and increases in-fiber chromatic dispersion. The ideal operating mode for optical telecommunications is that of maintaining a constant light intensity while modulating circular polarization. Another disadvantage of this architecture is that the placement of spin injectors around the mesa base of the laser requires, in addition to longitudinal transport, lateral spin transport over several micrometers so that the spin electrons, which are also what are referred to as the illumination electrons generating the light emission, reach the active region of the laser. This greatly decreases spin injection efficiency due to the limited spin diffusion length in GaAs (˜μm), thus preventing high circular polarization from being obtained.

One aim of the present invention is to rectify the abovementioned drawbacks by proposing a spin-LED or spin-laser light emission system, achieving rapid switching of the helicity of the circular polarization of emitted light, electrically controlled using an original spin injector structure that makes it possible to obtain a high polarization Pc and continuous-mode operation of the device.

### SUMMARY OF THE INVENTION

The present invention relates to a spin-LED or spin-laser light emission system comprising:
a stack deposited on a substrate along an axis Z perpendicular to the plane XY of the substrate and comprising an active layer and transport layers,
an electrode referred to as anode and an electrode referred to as cathode, configured to generate charge carriers that pass through the stack to the active layer,
a device referred to as spin injector, deposited on said stack and comprising:
an assembly of at least one first layer made of ferromagnetic material and at least one second layer made of metal material, said assembly having a bar structure referred to as a Hall bar along an axis X and having a first end and a second end,
a first electrode and a second electrode, referred to as spin electrodes, in electrical contact with the first and the second end of the Hall bar, respectively, and configured to generate, in the Hall bar, a pulsed current I along the axis X in a first direction or a second direction opposite the first direction,
the emission system being configured such that the cathode is in electrical contact with the Hall bar of the spin injector,
said spin injector being configured to have a magnetization along Z and such that a reversal of the direction of the current I reverses the direction of the magnetization, switching of the magnetization of the spin injector inducing a change in the circular polarization state of light emitted by the emission system.

According to one variant, the emission system according to the invention is a spin-laser emission system, wherein the stack furthermore comprises a first mirror positioned on the substrate and a second mirror arranged such that the injector is positioned inside an optical cavity formed by the first and the second mirror.

According to one embodiment of the spin-laser emission system, the second mirror is positioned on the spin injector and is a Bragg mirror.

According to one embodiment, a length of the Hall bar is greater than or equal to 2.5 times a width of said Hall bar.

According to one embodiment, the light emission system according to the invention furthermore comprises a thin insulating layer positioned between the spin injector and the stack.

According to one embodiment, the light emission system according to the invention furthermore comprises a masking layer opaque to emitted light, positioned on the spin injector, and having a circular surface opening inscribed in the Hall bar and delimiting the light emission zone.

According to one embodiment, the first layer, the second layer and, where applicable, the thin insulating layer each have a thickness less than 5 nm.

According to one embodiment, the stack is configured such that a distance between the spin injector and the active layer is less than 100 nm.

According to one embodiment, the cathode and one of the spin electrodes form a single electrode.

According to one embodiment, the cathode is in contact with the Hall bar via a side wall of the Hall bar.

According to one embodiment, the light emission system according to the invention furthermore comprises an additional electrode in electrical contact with the Hall bar via a side wall on the side opposite the cathode.

According to one embodiment, the light emission system according to the invention furthermore comprises a device for generating what is referred to as an external magnetic field along the axis X.

According to one embodiment, the stack is surrounded by an insulating material and forms, with the stack, a planar upper surface on which the spin injector and the cathode are positioned.

The following description presents several exemplary embodiments of the device of the invention: these examples do not limit the scope of the invention. These exemplary embodiments not only contain the features essential to the invention but also additional features associated with the embodiments in question.

### BRIEF DESCRIPTION OF THE DRAWINGS

The invention will be better understood and other features, aims and advantages thereof will become apparent from the following detailed description, which is provided with reference to the appended drawings, which are given by way of non-limiting examples and in which:

FIG. 1, already cited, illustrates the architecture of a spin LED according to the prior art.

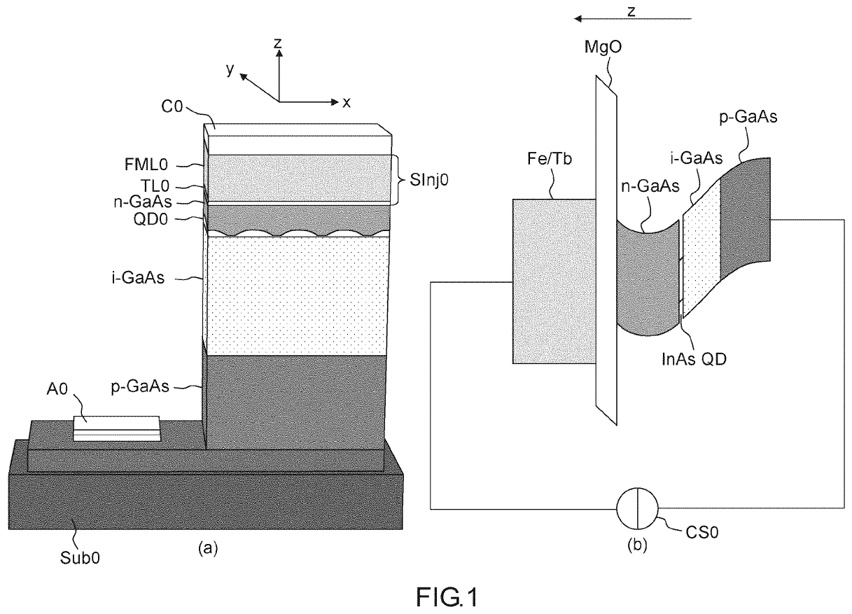

FIG. 2, already cited, illustrates the architecture of a spin LED having a quantum dot-based active layer according to the prior art.

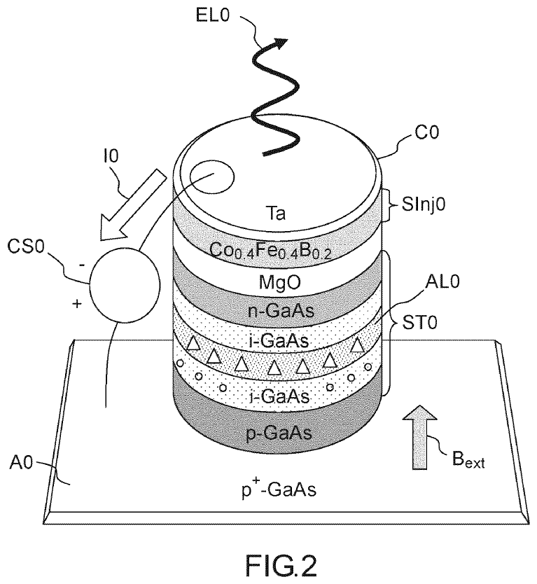

FIG. 3, already cited, illustrates, for the spin LED of FIG. 2, the switching from one circular polarization to the other as a function of an applied external magnetic field.

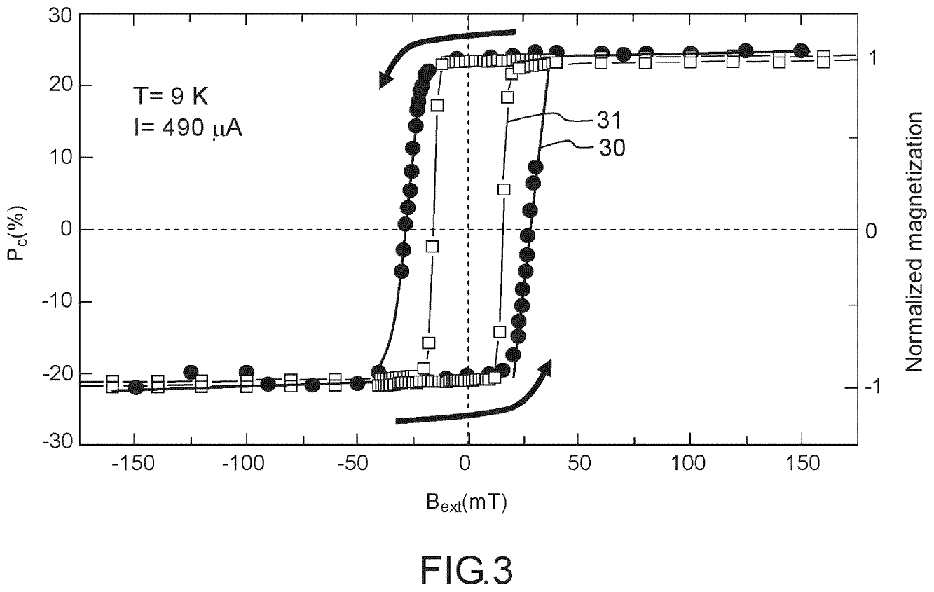

FIG. 4, already cited, illustrates a spin laser having two spin injectors enabling electrical switching of circular polarization according to the prior art.

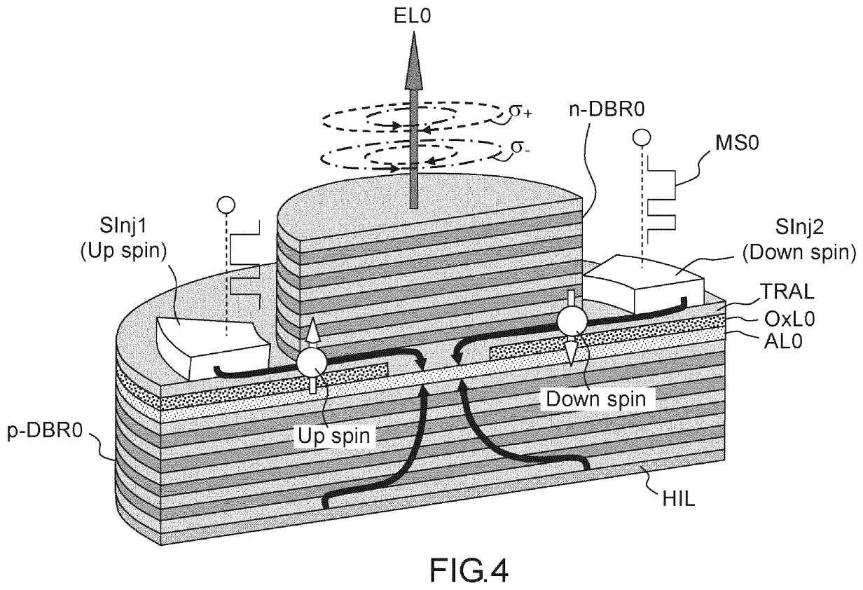

FIG. 5 illustrates a spin-LED emission system according to the invention, according to a first variant (profile view).

FIG. 6 illustrates the spin-laser emission system according to the invention, according to a first variant (profile view).

FIG. 7 illustrates the operating principle of the spin injector according to the invention.

FIG. 8 illustrates a first embodiment of the emission system according to the invention in which the cathode and the second spin electrode form a single electrode (plan view).

FIG. 9 illustrates a second embodiment of the emission system according to the invention in which the cathode is in contact with the Hall bar HB via a side wall (plan view).

FIG. 10 illustrates the principle of the spin Hall effect.

FIG. 11 illustrates the operation of the spin injector according to the invention for the first embodiment.

FIG. 12A illustrates the operation of the spin injector according to the invention for the second embodiment.

FIG. 12B illustrates the temporal dependence of the 3 magnetization components, respectively Mx, My and Mz, for a spin injector according to the invention for the second embodiment. The magnetic switching obtained by injecting a pulsed current, with an initial magnetization of the ferromagnetic layer oriented along Z and the current pulse is applied without an external magnetic field (Hext=0).

FIG. 12C illustrates the temporal dependence of the 3 magnetization components, respectively Mx, My and Mz, for a spin injector according to the invention for the second embodiment. The magnetic switching obtained by injecting a pulsed current, with an initial magnetization of the ferromagnetic layer oriented along Z and for which the current pulse is applied in the presence of a magnetic field of 0.04 T oriented along the direction X of the current.

FIG. 13 illustrates a spin-LED emission system according to the invention, according to a second variant (profile view).

FIG. 14 illustrates the spin-laser emission system according to the invention, according to a second variant (profile view).

FIG. 15 illustrates one embodiment of a spin laser according to the invention in which the second mirror of the spin laser is positioned on the Hall bar and is a Bragg mirror, like the first mirror.

FIG. 16 illustrates the first (A) and second (B) embodiments applied to the second variant of the system according to the invention.

FIG. 17 illustrates the variation in the abnormal Hall resistance as a function of the pulse intensity injected into the Hall bar.

### DETAILED DESCRIPTION

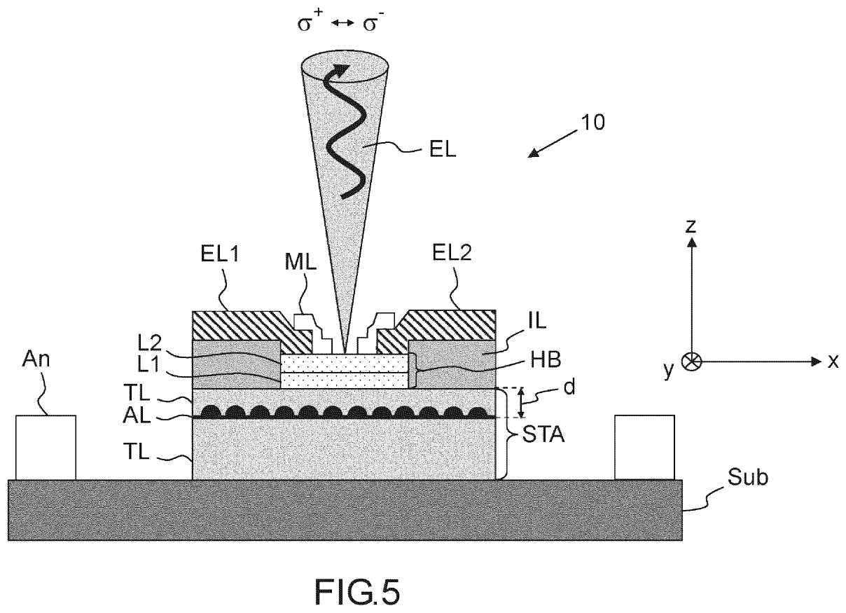

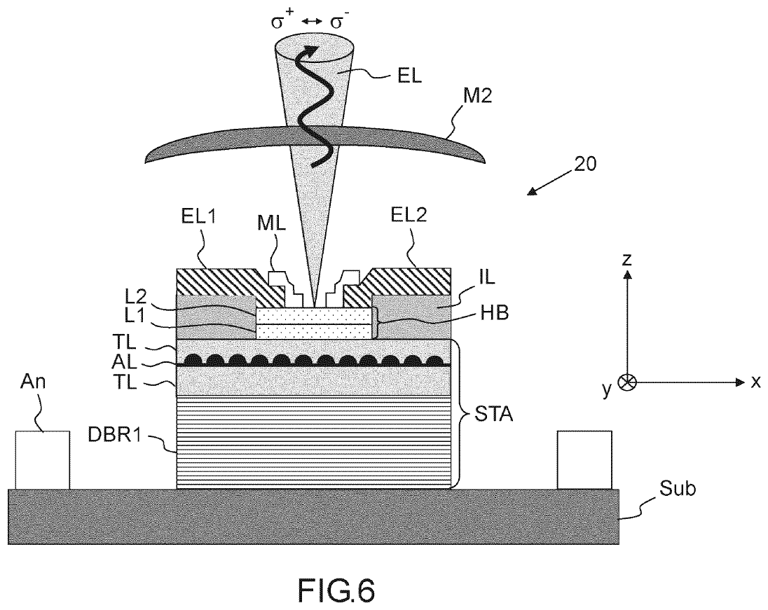

The spin-LED emission system 10 according to the invention and the spin-laser emission system 20 according to the invention are illustrated respectively in FIGS. 5 and 6 (profile views). The system comprises a stack STA deposited on a substrate Sub along an axis Z perpendicular to the plane XY of the substrate, the stack comprising an active layer AL and transport layers. According to one embodiment, the active layer comprises quantum dots (QD) or quantum wells (QW) in a single or multilayer configuration. The substrate, the transport layers and any other additional layer that makes it possible to obtain light emission of the LED or of the laser are conventional and will not be described. For example, the substrate and the various layers for light emission are based on GaAs or GaN or GaSb or another Ill-V compound, or a combination thereof.

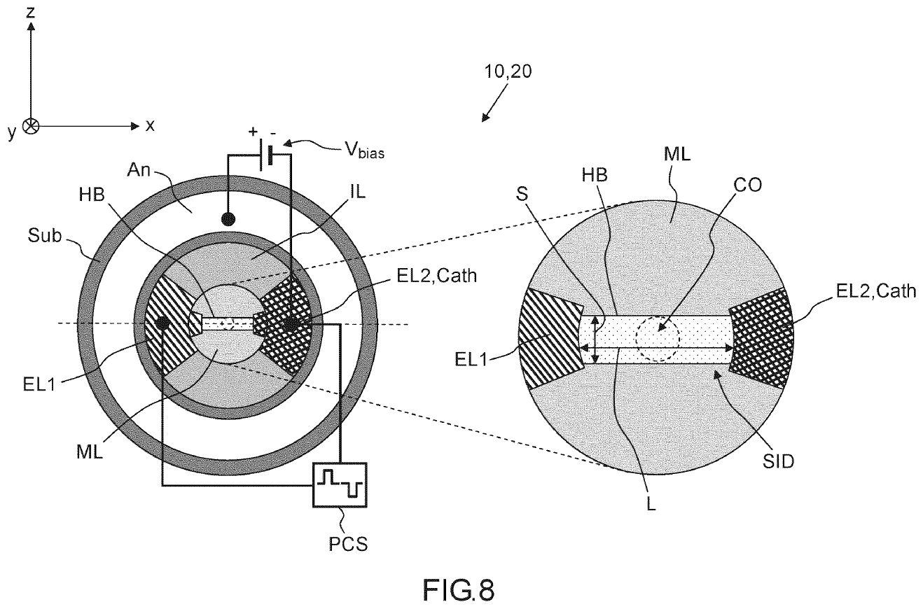

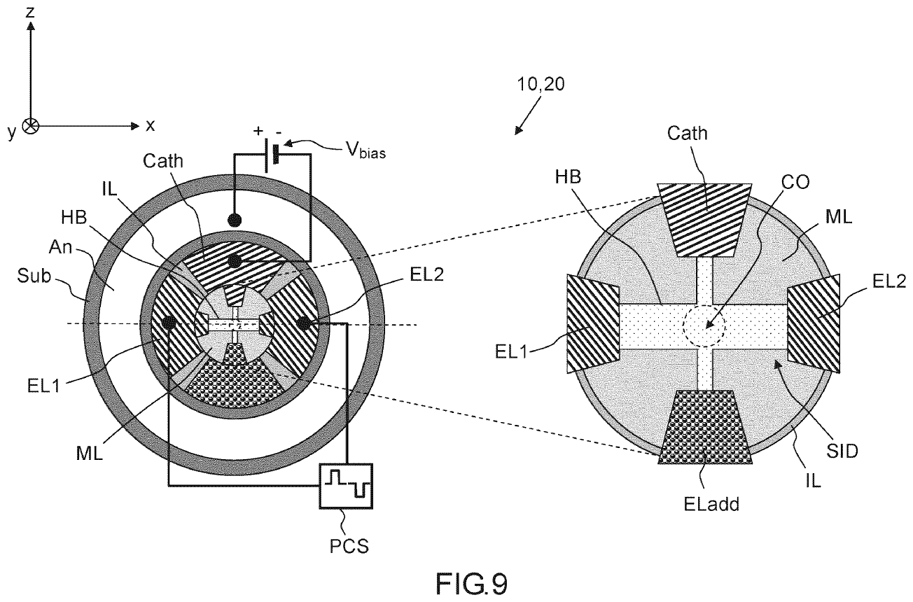

The emission system 10 or 20 also comprises an electrode referred to as anode An and an electrode referred to as cathode Cath, configured to generate charge carriers that pass through the stack to the active layer. The charge carriers injected by the anode are typically holes, and the charge carriers injected by the cathode are electrons, referred to as emission electrons. Typically, the electrons and the holes recombine radiatively so as to generate a light emission EL, as is conventional. The cathode Cath may be positioned in two different ways and is not illustrated in FIGS. 5 and 6, but is illustrated in FIGS. 8 and 9 described later. The cathode and the anode are for example, and as is conventional, made of a material typically consisting of a titanium and gold bilayer (Ti(10 nm)/Au(50 nm)) or of an AuGeNi alloy in order to avoid Schottky contact with n-type semiconductors.

The emission system according to the invention also comprises what is referred to as an original spin injector device SID, deposited on the stack STA. The injector SID comprises an assembly of at least one first very thin layer L1 of ferromagnetic material Mfer and at least one second very thin layer L2 of metal material Mmet.

Preferably, the metal Mmet is a heavy metal, such as tantalum (Ta), tungsten (W), bismuth (Bi), platinum (Pt), terbium (Tb) or any alloy of these materials. A heavy metal is understood to mean a metal having a high atomic number benefiting from strong spin-orbit coupling (in particular at the Fermi level).

Typically, the ferromagnetic material Mfer is chosen from: CoFeB, Co, Fe, CoFe, FePt, CoPt, FeTb or any alloy of the same type (transition metals and possibly rare earths).

According to one embodiment, the assembly comprises a single layer of each material and, according to another embodiment, the assembly comprises multiple layers of one or the other of the materials, or even layers of other elements, in a multilayer arrangement.

In one variant, the assembly also comprises a layer of a material with high electron conduction (Cu, Au, etc.) in order to amplify the effects of extrinsic or intrinsic SOT close to the interfaces (see below), as in the case of Pt.

Each layer is ultra-thin, typically with a thickness less than 10 nm, preferably less than 5 nm, possibly down to a lower limit of 1 nm (CoFeB). The assembly L1/L2 has a bar structure, referred to as a Hall bar HB, along an axis X, and has a first end and a second end. The bar HB has a small thickness e, typically less than 10-20 nm, a width S along Y and a length L along X. A bar shape is understood to mean an element of elongate shape, with a length L greater than or equal to 2.5 times the width S, preferably greater than or equal to 4 or 5 times S. By way of non-limiting example, the length L is of the order of 100-150 μm, and the width S is of the order of 20-50 μm.

The injector SID also comprises a first electrode EL1 and a second electrode EL2, referred to as spin electrodes, in electrical contact with the first and the second end of the Hall bar HB, respectively, and configured to generate, in the Hall bar, a pulsed current I along the axis X in a first direction s1 or a second direction s2 opposite the first direction. Preferably, in order to simplify the fabrication of the contact electrodes, all of the electrodes (therefore including the anode and the cathode) are made of the same material, for example a titanium and gold bilayer (Ti/Au).

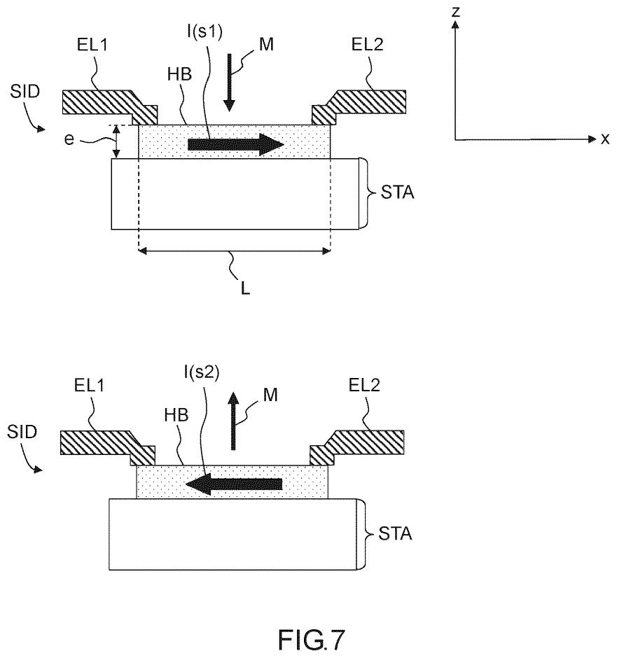

FIG. 7 illustrates the operating principle of the injector, which will be described in more detail below. The injector is based on the use of spin-orbit coupling, giving rise to a spin-orbit torque (SOT) effect, realized by the spin Hall effect (SHE). SOT-SHE is described for example in the publication “Spin Torque Switching with the Giant Spin Hall effect of Tantalum” by Liu et al. (Science VOL 336, 555, 2012). The Hall bar is typically produced by lithography.

The ferromagnetic layer L1, and therefore the injector SID, is configured to have a magnetization M component Mz along the axis Z (perpendicular magnetic anisotropy or PMA). A low-intensity static field Hₑₓₜ, aligned along the axis X, imposes a non-zero magnetization component Mx along the axis X. The SHE allows spin-polarized electrons to interact with the ferromagnetic by exerting a torque τ_{SOT} aligned on the axis Y, the sign of which depends on the direction of the current. The torque τ_{SOT} manifests itself as the result of an effective field H_{SOT} along the axis X. When this effective field H_{SOT} and the field Hₑₓₜ add together in the same direction, and for injected current densities greater than a certain critical current density, this causes a changeover or switch of the magnetization. If their directions are opposite, no changeover takes place, the state is stable and remains stable after the injection current has been removed. The spin injector according to the invention using the SHE is configured such that reversal of the direction of the current I reverses the direction of the component Mz of the magnetization M. By way of example, a current I (conveyed by the spin electrons) injected in a first direction s1 induces magnetization along Z oriented in a downward direction, and a current I injected in a second direction s2 induces magnetization along Z oriented in an upward direction, as illustrated in FIG. 7. The injected current is pulsed, each current pulse possibly being very short, with a characteristic pulse duration that may be reduced to a few ps for example. The switching of the magnetization, carried out with a very short pulsed current, may be very rapid, thus allowing high-speed operation, that is to say high-speed polarization switching.

The emission system is furthermore configured such that the cathode Cath is in electrical contact with the Hall bar HB of the spin injector SID. The emission electrons pass at least partially through the injector and are influenced by the magnetization of the injector, this influence being reflected in a spin polarization of the emission electrons, and thus a predominantly LHCP or RHCP polarization emission, depending on the direction of M. Switching of the magnetization of the spin injector thus induces a change of the circular polarization state of light EL emitted by the emission system. Once the switching has taken place and the desired polarization state has been obtained by applying the pulsed current, it is no longer necessary to apply the pulsed switching current to continue emitting light in the obtained circular polarization. The pulsed current is used only to switch the magnetic magnetization and therefore to change the polarization of the emitted light.

FIGS. 5 and 6 illustrate a first variant in which an insulating material IL is deposited on the stack STA and around the injector, so as to be able to deposit the spin electrodes EL1 and EL2.

When the emission system is a spin laser 20, the stack STA furthermore comprises a first mirror DBR1 positioned on the substrate Sub and a second mirror M2 arranged such that the injector is positioned inside an optical cavity formed by the first and the second mirror. In the embodiment illustrated in FIG. 6, the mirror M2 is external, that is to say outside the stack+injector assembly. The first mirror DBR1 is typically a Bragg mirror, for example consisting of an alternation of GaAs and AlGaAs layers. The spin laser is a VECSEL.

Preferably, to avoid problems due to the insertion of the metal layers (L1+L2) into the optical cavity, the spin-laser emission system 20 is configured such that the spin injector is placed in a node of the standing electromagnetic field on the surface of the %-VCSEL structure. This makes it possible to minimize absorption by the ferromagnetic layer of the spin injector.

In order to solve the problem of a resistivity mismatch between metals and semiconductors, according to one preferred embodiment, the light emission system furthermore comprises a thin insulating layer TIL positioned between the spin injector and the stack (not shown in the figures), typically made of magnesium oxide MgO (also referred to as tunnel barrier). Preferably, this layer extends over the entire surface of the stack. In this case, the structure of the STA/HB assembly is semiconductor/insulator/ferromagnetic/heavy metal. One example of a structure is given by way of illustration: Semiconductor/MgO/CoFeB/Ta.

According to one embodiment, the light emission system according to the invention furthermore comprises an insulating masking layer ML positioned on the spin injector, and having a circular surface opening CO inscribed in the Hall bar and delimiting the light emission zone. The masking layer has a thickness determined such that it is opaque to the one or more wavelengths of the emitted light. The masking layer is for example made of SiO₂. In this case, the light emitted from the circular opening is compatible with the TEM₀₀ emission mode.

Because the spin injector is positioned just above the stack STA, it is possible to make the distance between the injector SID and the active layer very small. Preferably, the stack is configured such that the distance (d) between the spin injector and the active layer remains less than 100 nm.

According to a first embodiment illustrated in FIG. 8 (plan view), the cathode Cath and one of the spin electrodes (the second spin electrode EL2 in FIG. 8) form a single electrode. The pulsed current, the direction of which is changed at high speed, is sent to the injector channel (bar HB, spin electrodes EL1 and EL2) via the pulsed current generator PCS. Simultaneously, the injector is negatively polarized (voltage between the electrode An and the electrode Cath=EL2) using a “vertical” bias voltage Vbias (2-3 V) so as to have continuous laser emission. The polarization between σ⁺ and σ⁻ will therefore be modulated depending on the direction of magnetization M of the injector. This configuration of the Hall bar is simple. It does not make it possible to measure the abnormal Hall resistance RAHE.

According to a second embodiment illustrated in FIG. 9 (plan view), the light emission system 10 or 20 according to the invention has a cathode Cath in contact with the Hall bar HB via a side wall of HB. Like EL1 and EL2, it is positioned on the insulating material IL. Typically, if the cathode Cath (mid-point of HB) is considered to be the voltage reference, the potentials to be applied to the contacts EL1 and EL2 are opposite, and reverse each time switching takes place. The anode potential remains at Vbias.

The current I the direction of which is modulated/reversed at high speed is injected into the channel via EL1 and EL2, and a bias voltage Vbias is simultaneously applied between the anode An and the cathode Cath.

According to one sub-embodiment that is also illustrated in FIG. 9, the emission system furthermore comprises an additional electrode ELadd in electrical contact with the Hall bar HB via a side wall on the side opposite the cathode Cath. Preferably, the assembly EL1, EL2, Cath and ELadd forms a Hall cross symmetrical structure. This additional electrode makes it possible, during characterization of the system, to measure the abnormal Hall resistance RAHE, which is equal to the ratio between the voltage measured between Cath and ELadd and the density of the injected pulsed current I between EL1 and EL2. This measurement makes it possible to probe the direction of magnetization M.

The advantages of the emission system according to the invention are manifold and are due to the original structure of the spin injector SID.

First of all, switching speed, based on circular polarization modulation, is in principle limited by the switching time of the magnetization of the spin injector, which approaches 200 GHz, thereby enabling an operating speed around 6 times faster than that of conventional intensity modulation (35 GHz for the prior art in VCSELs). This speed is obtained because it is no longer necessary to switch an external magnetic field in order to switch M.

Second of all, energy consumption is very low in the spin laser. This is because, on the one hand, the threshold current is reduced, since this reflects a population of out-of-equilibrium carriers in a single spin category, which is therefore increased with circular (optical or electrical) pumping, and, on the other hand, it is possible to reach the highest bit rates just above the threshold.

Third of all, the degree of circular polarization of coherent light is able to be modulated continuously as a function of the direction of magnetization of the spin injector. In other words, the emission system according to the invention is able to emit continuously, the switching of M being controlled independently of the generation of emission electrons. Thus, by virtue of the spin injector according to the invention, polarization acts as an additional coding dimension that leads to an increase in optical transmission bandwidth.

The spin injector is also very thin (for example with a thickness less than 5 nm when each of the two layers L1, L2 is of the order of 2 nm), thereby allowing it to be integrated into the optical cavity for spin lasers, due to its very low optical absorption loss. In this case, the distance between the spin injector and the active region is very small (<100 nm), thereby making it possible to efficiently inject spin-polarized electrons into the active region, thereby leading to good circular polarization Pc of the light emission.

The physical effect at the origin of the switching of the magnetization M of a bilayer via the current flowing through it is detailed below, and described in the publication “Current-induced switching of perpendicularly magnetized magnetic layers using spin torque from the Spin Hall effect” by Liu et al (Physical Review Letters, 109, 096602 (2012)).

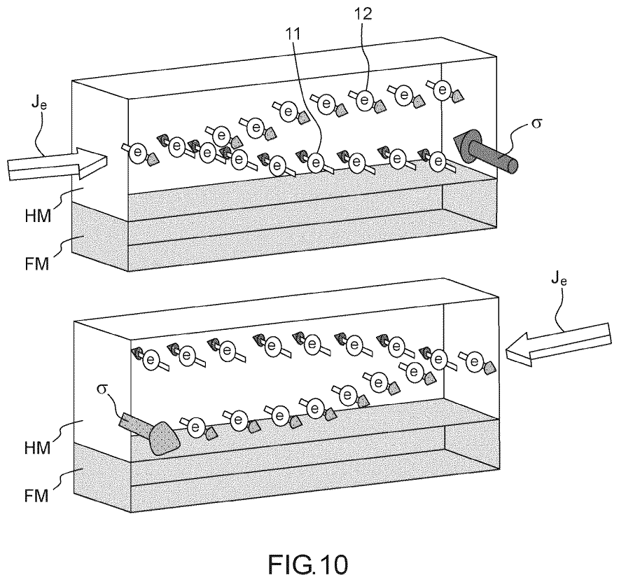

By using the spin Hall effect SHE via spin-orbit coupling SOT, it is possible to electrically switch the magnetization M of a ferromagnetic metal FM/heavy metal HM bilayer. When a charge current Je is injected into the layer HM, due to the spin Hall effect via spin-dependent diffusion, electrons having opposing spins 11, 12 will tend to accumulate on the upper and lower surfaces of the layer HM, as illustrated in FIG. 10. When Je changes direction, an electron spin with a different direction accumulates at the interface HM/FM, resulting in an opposing spin polarization U.

At the interface HM/FM, the spin polarization generated by out-of-equilibrium spin accumulation 6 produces a spin-orbit torque \vec{τ}_{SOT} on the magnetization M of the adjacent layer FM according to the formula:

$${\vec{τ}}_{SOT} = \vec{M} \times \vec{σ} \times \vec{M} .$$

The spin-orbit torque \vec{τ}_{SOT} generates an effective field \vec{H}_{SOT} that makes it possible to switch the magnetization of the ferromagnetic layer FM. The switching may take place at very high speed (see the publication Jhuria et al “Spin-orbit torque switching of a ferromagnet with picosecond electrical pulses”, Nature Electronics, 3, 680 (2020)).

The original idea of the invention is that of using this switching effect to produce a new type of spin injector for a spin LED or spin laser.

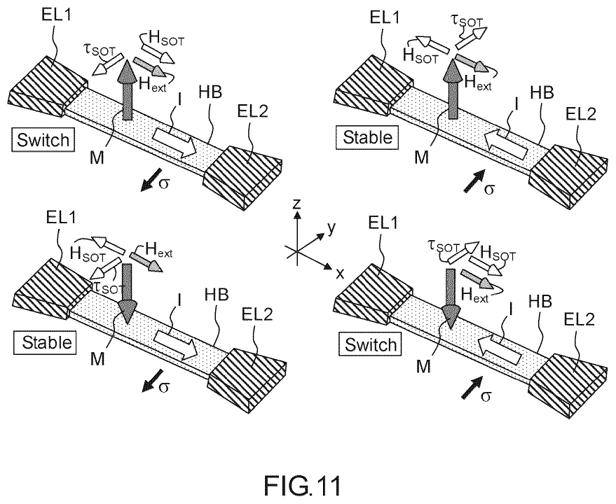

FIG. 11 schematically shows the magnetization switching used in the Hall bar structure HB of the injector according to the invention for the four situations with different directions of \vec{M} and of I, for an injector according to the first embodiment (EL2=Cath).

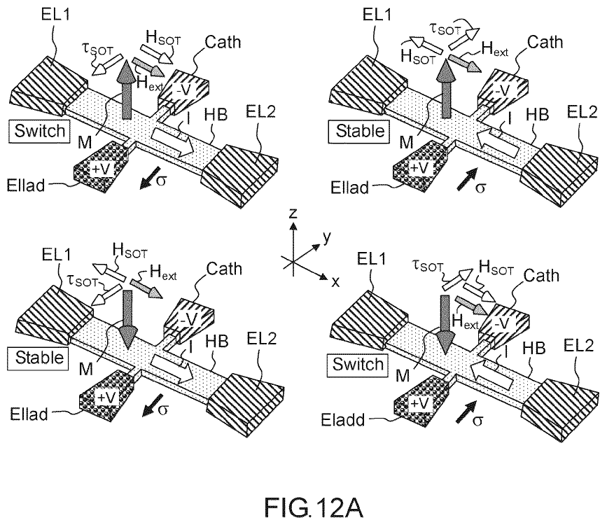

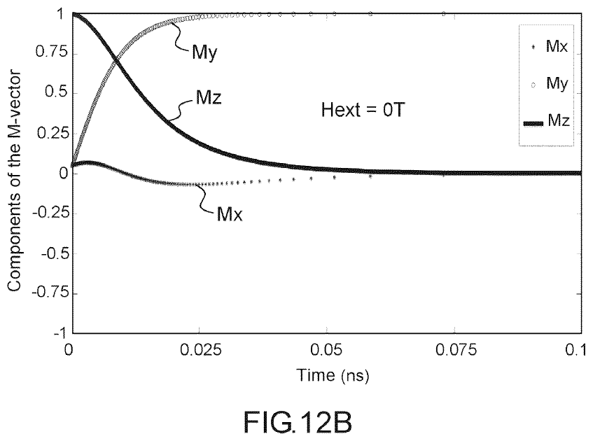

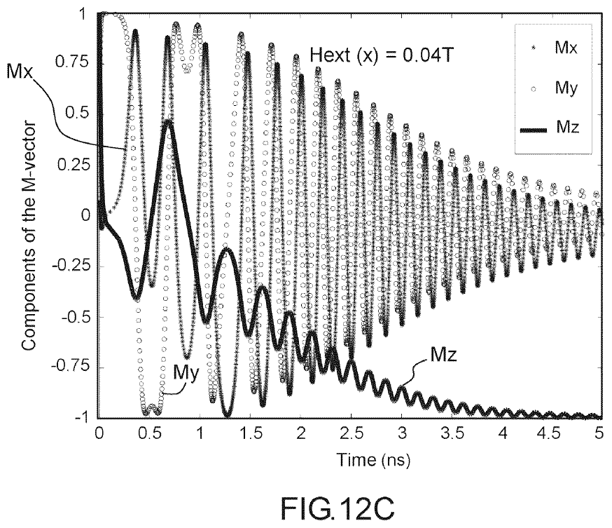

FIG. 12A schematically shows the magnetization switching used in the Hall bar structure HB of the injector according to the invention for the four situations with different directions of \vec{M} and of I, for an injector according to the second embodiment (EL2 distinct from Cath). To evaluate the abnormal Hall resistance RAHE, it is necessary to measure the potential difference that occurs between the 2 electrodes Cath and ELadd during the application of the control current I.

The emission electrons are injected into a magnetized medium that they pass through, their spin direction aligns with the direction of magnetization of the magnetized material, then they descend into the semiconductor structure. In other words, the current in the lateral HB, which may switch the magnetization, controls the spin of the emission electrons.

The electrons coming from the generator of Vbias that will pass through the semiconductor zone will all pass through the ferromagnetic layer, the magnetization of which will contribute to polarizing the spin. Once the magnetization of the ferromagnetic layer has been oriented, the electron flux (coming from the generator Vbias) containing the same number of up and down spins will not change the magnetization of the ferromagnetic material, but this flux will spin-polarize. To obtain deterministic perpendicular magnetization switching, according to one embodiment, a small external magnetic field \vec{H}ₑₓₜ is applied along the direction X of the injector channel. There are two reasons for this. The first reason is that the applied magnetic field \vec{H}ₑₓₜ, even though it is weak, may help the effective field \vec{H}_{SOT} to switch \vec{M} when they are in the same direction, as shown in FIGS. 11 and 12 for the case “switch”. The second reason is that this same field \vec{H}ₑₓₜ will cancel out \vec{H}_{SOT} so as to stabilize a particular magnetization orientation when they are in opposing directions. When injecting an opposing current direction into the channel, the direction of magnetization of the injector may then be controlled. The value of the field \vec{H}ₑₓₜ that is required is small, typically less than or equal to 100 mT (see the publication by Liang et al “Electrical switching of perpendicular magnetization in a single ferromagnetic layer”, Phys. Rev. B 101, 220402 2020). Typically, the magnetic field \vec{H}ₑₓₜ represents, in terms of value, a fraction of the perpendicular magnetic anisotropy that makes it possible to keep the magnetization out-of-plane.

Thus, for this embodiment, the emission system comprises a device for generating the external magnetic field \vec{H}ₑₓₜ along the axis X. This field \vec{H}ₑₓₜ does not need to be switched in order to achieve switching of M. To probe the direction of magnetization, it is possible to measure the abnormal Hall resistance R_{AHE} via the abovementioned additional electrode ELadd.

FIGS. 12B and 12C illustrate one example of a magnetic switching simulation obtained by injecting a pulsed current of 150 ps and of amplitude Js=4×10⁸ A/cm², and with an initial magnetization of the ferromagnetic layer oriented along Z (Mz=+1).

The structure of the ferromagnetic layer is considered here to be uniform and therefore consists of a magnetic monodomain (the perpendicular magnetic anisotropy here is 0.5 T and the damping coefficient α=0.01). The two layers used for the simulation are a 1-nm CoFeB layer and a 3-nm Pt layer.

FIG. 12B illustrates the case in which the current pulse is applied without an external magnetic field (Hₑₓₜ=0). FIG. 12C illustrates the case in which the current pulse is applied in the presence of a magnetic field of 0.04 T oriented in the direction X of the current. For each case, the temporal dependence of the 3 magnetization components, Mx, My and Mz, respectively, is described.

In the case Hext=0, the magnetic torque acting on the magnetization initially oriented along the axis z normal to the plane of the multilayers allows the magnetization to be set in motion, giving rise to the other two components, My and Mx. The stabilization of the magnetization at long times is obtained relatively quickly, and equilibrium is obtained for a magnetization in the plane oriented along the axis Y transverse to the direction X of the injected current pulse. The magnetic torque is not sufficient in this case to completely reverse the magnetization in the direction −Z as desired, and the final state will be non-deterministic, characterized by a magnetization state +/−Z along the normal.

In the case Hext(x)=0.04 T, the application of a small magnetic field of 0.04 T along the axis X breaks this particular symmetry of the spin Hall effect and, under the same experimental conditions, the current pulse then makes it possible to completely reverse the magnetization along the direction −Z as desired, despite the multiple precessions revealing strong magnetic oscillations giving rise to the occurrence of the components Mx and My. In this example, the stabilization time is of the order of 1 ns, and the current pulse of 150 ps is sufficient to completely reverse the magnetization in the desired direction. Optimizing the pulse duration at shorter times allows faster magnetic switching so as to achieve the desired performance in terms of information transfer frequency.

According to other embodiments, the use of an external magnetic field is avoided by using various strategies.

According to a first embodiment, a lateral structural asymmetry of the bar HB is created, which gives rise to a new spin-orbit torque when the current is injected into the bar. The direction of the effective field induced by the current corresponding to this spin-orbit torque is out-of-plane, thereby facilitating the switching of perpendicular magnets (see the publication Yu et al., “Switching of perpendicular magnetization by spin-orbit torques in the absence of external magnetic fields”, Nature nanotechnology, 9, 548 (2014)).

According to a second embodiment, the ferromagnetic layer L1 is a ferromagnetic alloy film with a non-uniform composition (see the abovementioned publication Liang et al “Electrical switching of perpendicular magnetization in a single ferromagnetic layer”, Phys Rev B 101, 220402 (R), 2020), which generates an electric field along the normal to the plane of the layer and consequently an in-plane magnetic field (which is the one sought) to assist the switching, by way of the abovementioned spin-orbit coupling.

According to a third embodiment, the one (or more) multilayers are grown on a substrate characterized by a specific orientation (111) and giving rise to a monocrystalline structure that is well defined overall. The associated magnetic anisotropy will comprise a term defining an in-plane effective magnetic field, the one sought for switching. The occurrence of such a magnetic field in the plane of the layers is the consequence of a break of inversion symmetry in this same plane, generating additional spin-orbit torques that are able to be exploited in this case (see the publication Liu et al “Symmetry dependent field-free switching of perpendicular magnetization”, Nature technology, 16, 277-282, 2021).

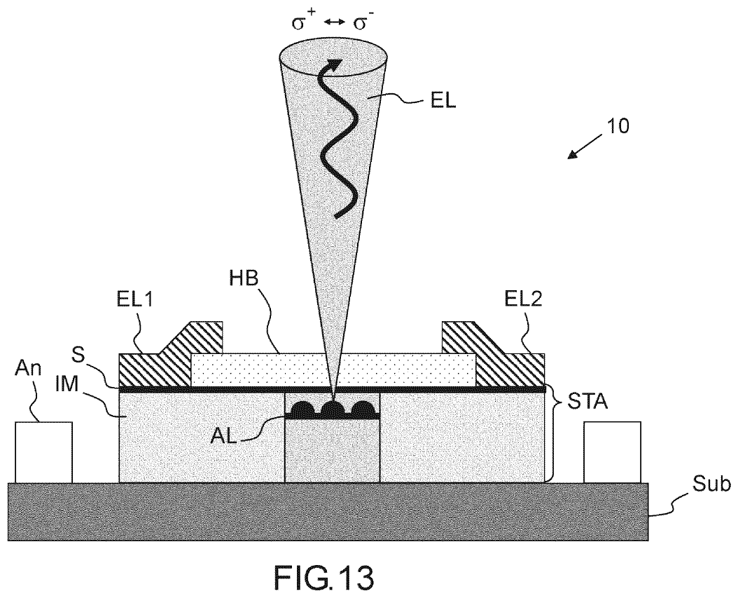

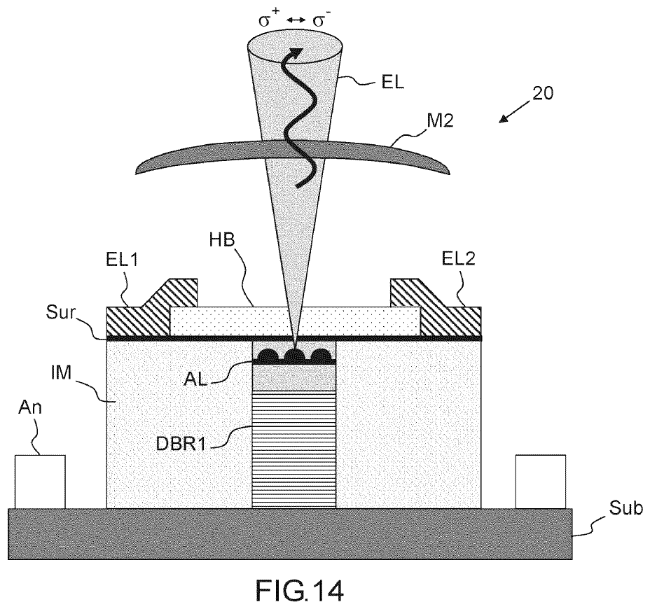

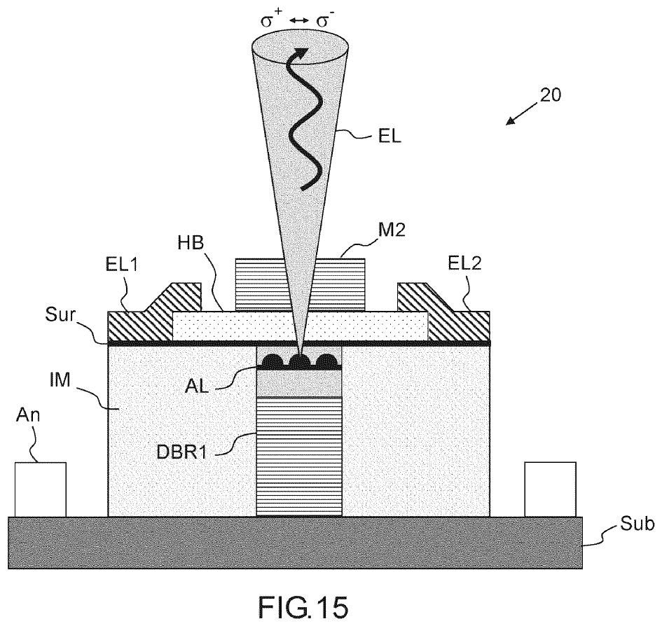

To guarantee that the current injected along the vertical (direction Z) for the laser emission is injected homogeneously into the active zone AL of the spin laser, an arrangement is created such that the surface of the spin injector bar HB covers the entire surface of the active layer and more. For this purpose, according to a second variant, the stack STA is surrounded by an insulating material IM (for example a BCB photosensitive resin) and forms, with the stack, a planar upper surface Sur on which the spin injector and the cathode are positioned, as illustrated in FIG. 13 for the spin LED and FIGS. 14 and 15 for the spin laser.

According to one embodiment, the second mirror M2 of the spin laser is positioned on the bar HB, as illustrated in FIG. 14. The second mirror M2 may also be replaced by a Bragg mirror, as illustrated in FIG. 15. One advantage is that of making the spin laser more miniaturized. This also makes it possible to considerably reduce the cost of the system and improve the reliability of the component.

In these examples, the stack STA is, by way of illustration, cylindrical (for example with a diameter of 50 μm) and the insulating material positioned around the stack is also cylindrical. The anode is positioned on the substrate Sub and is in the shape of a ring surrounding the cylinder. The width S of the bar HB is chosen to be substantially equal to 50 μm, that is to say to the diameter of the stack.

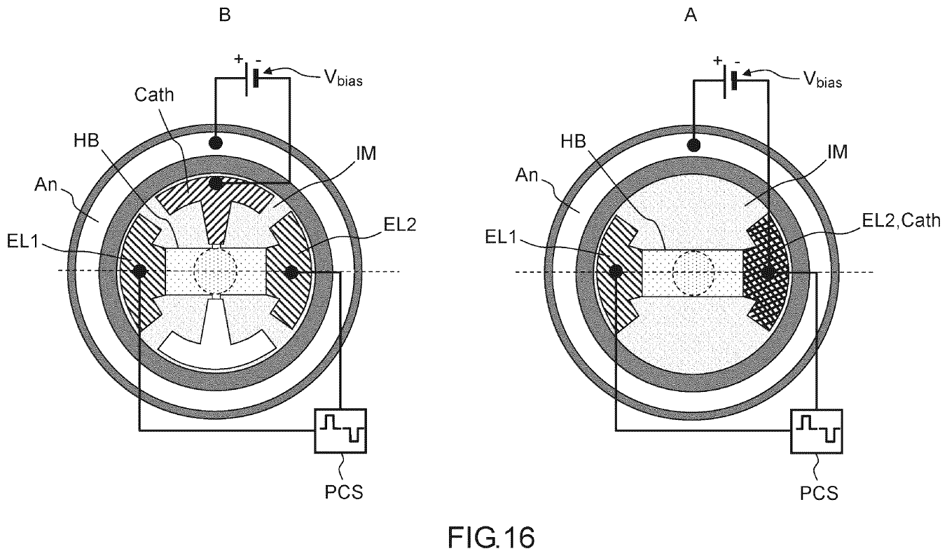

This second variant, also illustrated in FIG. 16, is compatible with the first embodiment (A) with a cathode coinciding with the second spin electrode, and with the second embodiment (B) with a lateral cathode.

To fabricate the emission system, the semiconductor micropillar, with a diameter of 50 μm, is first fabricated by lithography. Next, the surrounding zone is filled with an insulating material (for example a BCB photosensitive resin) so as to obtain a planar surface Sur. The layers of the spin injector are deposited on the surface Sur, and a lithography step forms the bar structure. Since the surface of the bar HB may cover the entire surface of the semiconductor micropillar, the current injected for laser emission flows homogeneously in the active zone of the semiconductor. In this design, the insulating opaque cover layer ML is no longer required and the entire stack emits light. However, with this structure, it may be problematic to obtain a clean injector/semiconductor interface, which could influence spin injection efficiency. Since the lithography procedure contributes residual adhesive or defects to the surface of the semiconductor, it is necessary to carry out appropriate chemical cleaning on the surface of the semiconductor before depositing the spin injector layers.

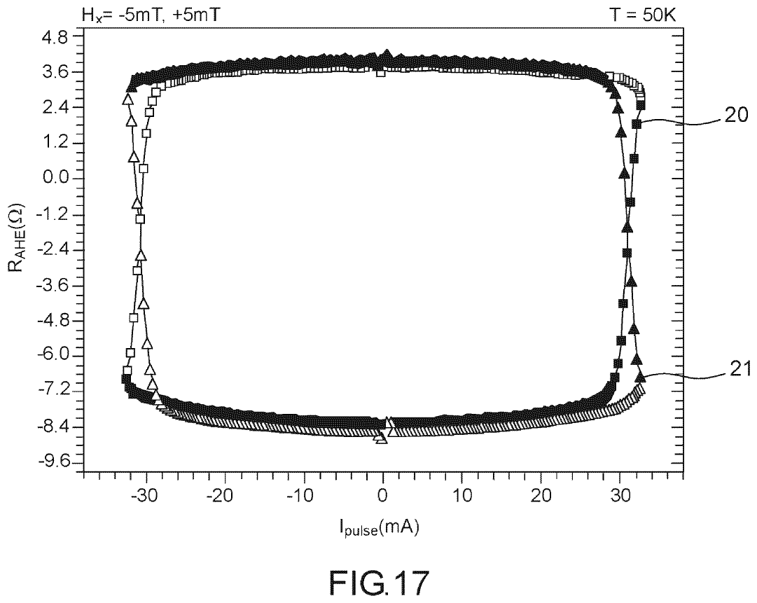

FIG. 17 illustrates the magnetization switching carried out with a spin injector SID according to the invention having a first example of a CoFeB (1.1 nm)/Ta (2 nm)/CoFeB (0.8 nm) multilayer structure deposited on an undoped GaAs substrate, with a layer TIL made of MgO (2.5 nm) between the injector and the substrate.

The multilayer structure is treated by UV lithography to fabricate the bar structure of the spin injector on top of the mesa. The SHE-based magnetization switching in a spin injector in the form of a Hall bar according to the invention is demonstrated by measuring the abnormal Hall resistance (RAHE, ratio between longitudinal voltage and transverse current on the Hall bar structure) as a function of the strength of the pulsed current iₚᵤₗₛₑ injected into the bar HB. For the experiment, a small external field Hext of +5 mT (curve 20) or −5 mT (curve 21) is applied. FIG. 17 shows that the magnetization is switched with a current strength of 30 mA at 50 K (pulse duration 100 μs).

1. A spin-LED or spin-laser light emission system comprising:
a stack (STA) deposited on a substrate (Sub) along an axis Z perpendicular to the plane XY of the substrate and comprising an active layer (AL) and transport layers, an electrode referred to as anode (An) and an electrode referred to as cathode (Cath), configured to generate charge carriers that pass through the stack to the active layer, a device referred to as spin injector (SID), deposited on said stack and comprising:
an assembly of at least one first layer (L1) made of ferromagnetic material and at least one second layer (L2) made of metal material, said assembly having a bar structure referred to as a Hall bar (HB) along an axis X and having a first end and a second end, a first electrode (EL1) and a second electrode (EL2), referred to as spin electrodes, in electrical contact with the first and the second end of the Hall bar, respectively, and configured to generate, in the Hall bar, a pulsed current I along the axis X in a first direction or a second direction opposite the first direction,
the emission system being configured such that the cathode is in electrical contact with the Hall bar of the spin injector,
said spin injector being configured to have a magnetization (M) along Z and such that a reversal of the direction of the current I reverses the direction of the magnetization (M), switching of the magnetization of the spin injector inducing a change in the circular polarization state of light (EL) emitted by the emission system.

2. The spin-laser emission system (20) as claimed in claim 1, wherein the stack furthermore comprises a first mirror (DBR1) positioned on the substrate and a second mirror (M2) arranged such that the injector is positioned inside an optical cavity formed by the first and the second mirror.

3. The spin-laser emission system (20) as claimed in claim 2, wherein the second mirror is positioned on the spin injector and is a Bragg mirror.

4. The light emission system as claimed in claim 1, wherein a length (L) of the Hall bar is greater than or equal to 2.5 times a width (S) of said Hall bar.

5. The light emission system as claimed in claim 1, furthermore comprising a thin insulating layer (TIL) positioned between the spin injector and the stack.

6. The light emission system as claimed in claim 1, furthermore comprising a masking layer (NIL) opaque to emitted light, positioned on the spin injector, and having a circular surface opening (CO) inscribed in the Hall bar and delimiting the light emission zone.

7. The light emission system as claimed in claim 1, wherein the first layer, the second layer and, where applicable, the thin insulating layer each have a thickness less than 5 nm.

8. The light emission system as claimed in claim 1, wherein the stack is configured such that a distance (d) between the spin injector and the active layer is less than 100 nm.

9. The light emission system as claimed in claim 1, wherein the cathode and one of the spin electrodes form a single electrode.

10. The light emission system as claimed in claim 1, wherein the cathode is in contact with the Hall bar via a side wall of the Hall bar.

11. The light emission system as claimed in claim 10, furthermore comprising an additional electrode (ELadd) in electrical contact with the Hall bar via a side wall on the side opposite the cathode.

12. The light emission system as claimed in claim 1, further comprising a device for generating what is referred to as an external magnetic field along the axis X.

13. The light emission system as claimed in claim 1, wherein the stack (STA) is surrounded by an insulating material (IM) and forms, with the stack, a planar upper surface (Sur) on which the spin injector and the cathode are positioned.
